(19) United States
(12) Patent Application Publication
(10) Pub. No.: US 2009/0160580 A1
(43) Pub. Date: Jun. 25, 2009

(54) COIL LEADING STRUCTURE AND FILTER THEREOF

(75) Inventors: Yu-Chen HSIEH, Taoyuan Hsien (TW); Chih-Tse Chen, Taoyuan Hsien (TW); Yi-Bin Lee, Taoyuan Hsien (TW)

Correspondence Address: Muncy, Geissler, Olds & Lowe, PLLC, P.O. BOX 1364, FAIRFAX, VA, 22038-1364, US

(73) Assignee: DELTA ELECTRONICS, INC.

(21) Appl. No.: 12/170,071

(22) Filed: Jul. 9, 2008

(30) Foreign Application Priority Data
Dec. 19, 2007 (TW) 96221612

(51) Int. Cl. H03H 7/00; H01F 27/02; H01F 27/06

(52) U.S. Cl. 333/185; 336/65; 336/92

(57) ABSTRACT

A filter includes a coil leading structure and at least one coil. The coil leading structure includes a board and at least one pin. The pin is disposed at a side of the board and formed integrally with the board as a monolithic piece. The core is disposed on the board and has at least one end to be coupled with the pin.

### CROSS REFERENCE TO RELATED APPLICATIONS

This Non-provisional application claims priority under 35 U.S.C. §119(a) on Patent Application No(s). 096221612 filed in Taiwan, Republic of China on Dec. 19, 2007, the entire contents of which are hereby incorporated by reference.

### BACKGROUND OF THE INVENTION

1. Field of the Invention

The invention relates to a coil leading structure and a filter thereof.

2. Description of the Related Art

As electronic products become more elaborate, the surface mount device (SMD) technology is usually used for connecting electronic elements to the printed circuit board of the electronic products. Conventional connecting technology via magnetic elements actually comprises two methods as follows.

One method is wrapping a wire on a core to form a coil. The coil is manually soldered on a pad of a printed circuit board via a soldering iron. A surface mount device (SMD) element is adhered to the printed circuit board. Then, a pin to electrically connect to an outer device is soldered in a hole of the printed circuit board. The coil is covered via a silica gel. Finally, the entire printed circuit board and elements thereon are sealed via an epoxy resin.

The other method is wrapping a wire on a core to form a coil. The coil is covered on a leadframe forming a mold of an SMD transformer. Thereafter, related electronic elements and the mold of the SMD transformer are adhered to a printed circuit board. Then, a pin to electrically connect to the outer device is soldered in a hole of the printed circuit board. Finally, the printed circuit board is assembled with a housing and sealed via an adhesive.

However, the two above-mentioned methods have some problems that must be solved. For example, in the first method, as coil integration increases, the amount of the coil increases. Thus, complexity of the manual manufacturing process increases, resulting in requirement for more skilled manual workers. However, even if skilled manual workers are provided, the soldering process is still repeated many times for ensuring a plurality of coil soldered completely. Thus, product reliability decreases and time for completion of the manufacturing process increases. The pins are inserted for connection and then are soldered manually. As integration increases, the amount of the pins increases. Difficulty of manual soldering increases, easily resulting in products with various length pins or inclined pins. Additionally, the silica gel used for manual mounting is inconsistent, thus, the quality of the soldered products are inconsistent. Furthermore, when a wrong proportion of the adhesive is used in potting and sealing processes, potting and sealing processes fail, affecting product appearance and property.

For the above-mentioned method, when molding the mold of the SMD transformer, a great quantity of lead in the solder pass muster does not pass environmental muster. Meanwhile, because elements of electronic products with high integration have limited space, the volume of the mold of the transformer decreases, resulting in lower reliability, lower yields and higher costs. Thus, probability for product failure increases for consumers. Similarly, because of limited space, the interval between pins of electric capacities on a printed circuit board and a mold of a transformer decreases, increasing failure probability, and decreasing stress resistance. Manually inserting pins and potting and sealing the adhesive generate disadvantages of the first method.

### BRIEF SUMMARY OF THE INVENTION

The invention provides a coil leading structure and a filter thereof that can solve the problem of difficult coil arrangements because of high integration of electronic elements so that the reliability and the manufacturing speed can be increased.

In order to achieve the above-mentioned objects, the invention provides a coil leading structure used with at least a coil, including a board and at least a pin. The coil is disposed on the board. The pin is disposed at a side of the board and formed integrally with the board as a monolithic piece. The coil includes at least an end coupled to the pin.

In order to achieve the above-mentioned, the invention provides a filter including a coil leading structure and at least a coil. The coil leading structure includes a board and at least a pin. The pin is disposed at a side of the board and formed integrally with the board as a monolithic piece. The coil includes at least an end coupled to the pin.

For the above-mentioned coil leading structure and filter thereof, the coil is vertically or horizontally disposed on the board. The end is correspondingly connected to the pin by welding, clipping or wrapping. Because the pin includes a recess so that the end of the coil is wound onto the recess and fixed by soldering. The recess has a semicircular, square, rectangular, cambered or other shape. Further, an adhesive covers the coil and is filled between the coil and the board. The board is a printed circuit board.

For the above-mentioned filter, the filter further includes a housing. The housing covers the outer portion of the coil leading structure. The filter can be applied to an electronic equipment of local area network or ethernet.

### BRIEF DESCRIPTION OF DRAWINGS

The present invention will become more fully understood from the detailed description given herein below and the accompanying drawings which are given by way of illustration only, and thus are not limitative of the present invention, and wherein:

FIG. 1A is a schematic view of a filter of an embodiment according to the present invention;

FIG. 1B is a vertical view of a coil leading structure of FIG. 1A; and

FIGS. 2A, 2B, 2C and 2D show four variations of a pin of the embodiment according to the present invention.

### DETAILED DESCRIPTION OF THE INVENTION

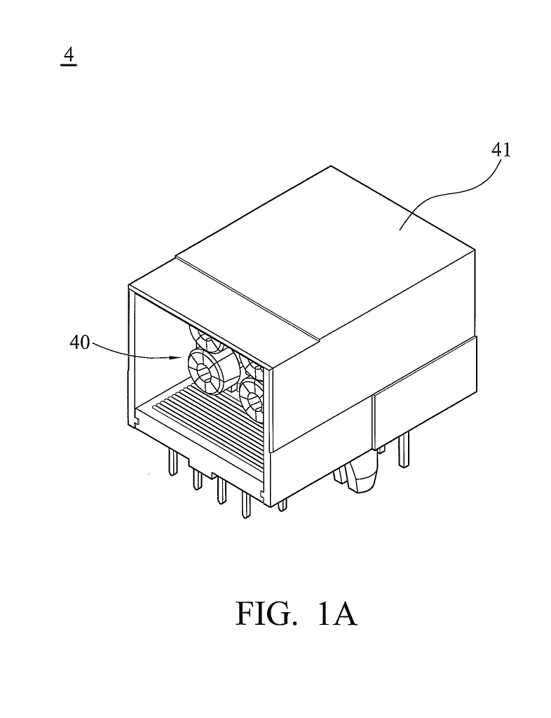

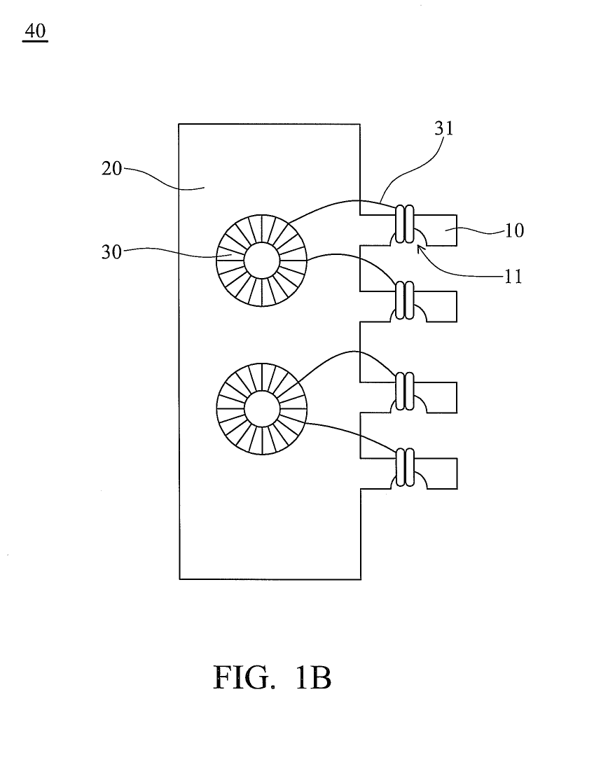

Referring to FIGS. 1A and 1B, FIG. 1A is a schematic view of a filter of an embodiment according to the present invention. FIG. 1B is a vertical view of a coil leading structure of FIG. 1A. As shown in FIG. 1A, a filter 4 includes a coil leading structure 40 and a housing 41. The housing 41 covers the outer portion of the coil leading structure 40. The coil leading structure 40 includes a board 20, at least a coil 30 and a plurality of pins 10. The board 20 is a printed circuit board, and the coil 30 is disposed on an upper surface of the board 20.

To solve the problem of difficult coil arrangements during the manufacturing process, the plurality of pins 10 are protruded from at least a side of board 20 of the coil leading structure 40. The plurality of pins 10 are formed integrally with the board 20 as a monolithic piece. The coil 30 includes at least an end 31 directly fixed to the pins 10 by welding, clipping or wrapping for electrical connection. Thus, the embodiment according to the present invention avoids the conventional method that the coil 18 is manually soldered on the board 12, eliminating the variable affecting inconsistent quality. The fixation with that via the pins saves the area of the board 12 occupied by the conventional mold so that the free area can be provided for other electronic elements such as resistors or electric capacitors. Compared with the conventional filter, the reliability and the manufacturing speed of the filter of the embodiment can be increased.

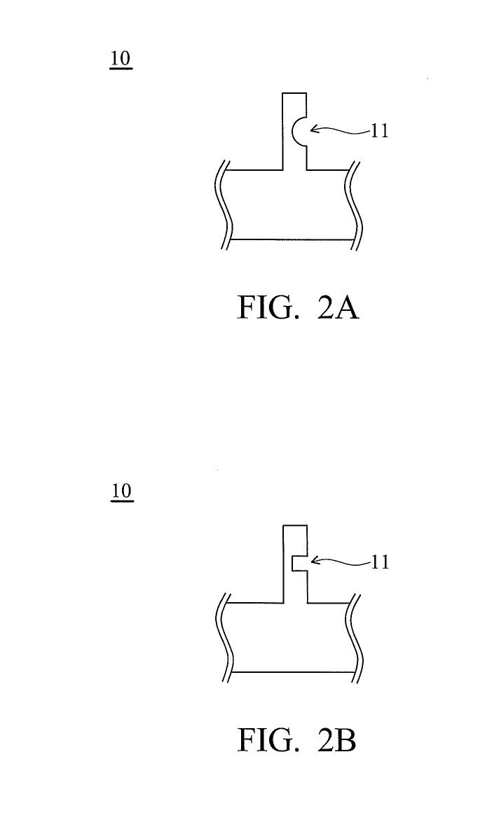

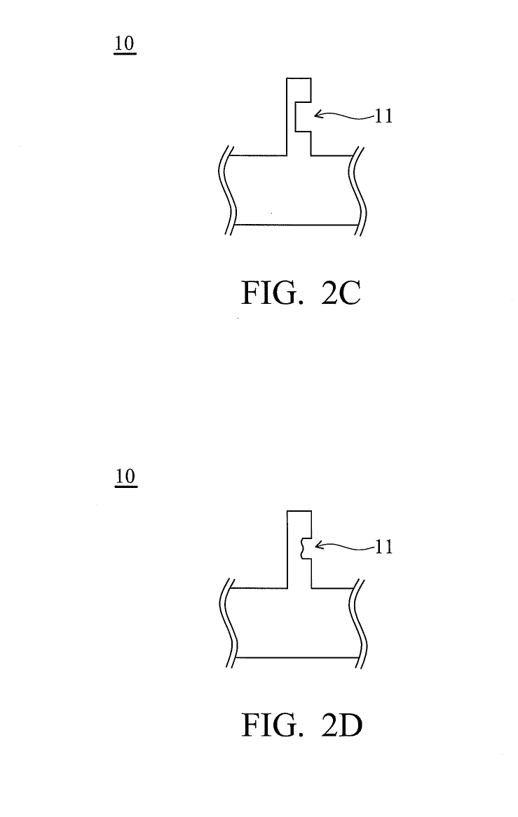

FIGS. 2A to 2D show four variations of the pin 10 of the embodiment according to the present invention. To easily connect the end 31 to the pin 10, a recess 11 is formed on each of the pins 10. The recess 11 can be semicircular as shown in FIG. 2A, square as shown in FIG. 2B, rectangular as shown in FIG. 2C, cambered as shown in FIG. 2D or other shape. The end 31 is wound onto the recess 11 and fixed by soldering. Thus, the end 31 is stably connected to the pin 10.

The present invention is not limited to the above-mentioned embodiments. The coil 30 can be vertically or horizontally disposed on the board 20 of the coil leading structure 40 according to product requirements. To enhance the combination of the coil 30 and board 20, the adhesive covers the coil 30 and is filled in the gap between the coil 30 and the board 20, not only protecting the coil 30 but also improving the stability of the coil 30 and the board 20.

In summary, compared with the conventional manually soldered structure, skilled workers for manufacturing the filter of the present invention do not need special training. Additionally, the filter of the present invention has high soldering efficiency and soldering quality so that the quality of integration of the electronic devices can be improved. The filter of the present invention does not spend costs for additional molding and eliminates additional procedures. The filter of the present invention shows outstanding properties which may be applied to related products such as electric devices of local area network or ethernet.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A coil leading structure used with at least a coil, the coil leading structure comprising:
a board for disposing the coil thereon; and
at least a pin disposed at a side of the board and formed integrally with the board as a monolithic piece;
wherein an end of the coil is coupled to the pin.

2. The coil leading structure as claimed in claim 1, wherein the coil is vertically or horizontally disposed on the board.

3. The coil leading structure as claimed in claim 1, wherein the end of the coil is correspondingly connected to the pin by welding, clipping or wrapping.

4. The coil leading structure as claimed in claim 1, wherein the pin comprises a recess.

5. The coil leading structure claimed in claim 4, wherein the recess has a semicircular, square, rectangular, cambered or other shape.

6. The coil leading structure claimed in claim 4, wherein the end of the coil is wound onto the recess and fixed by soldering.

7. The coil leading structure claimed in claim 1, further comprising an adhesive covering the coil and filled between the coil and the board.

8. The coil leading structure claimed in claim 1, wherein the board comprises a printed circuit board.

9. A filter comprising:
a coil leading structure comprising:
a board; and
at least a pin disposed at a side of the board and formed integrally with the board as a monolithic piece; and
at least a coil disposed on the board and comprising an end to be coupled with the pin.

10. The filter claimed in claim 9, wherein the coil is vertically or horizontally disposed on the board.

11. The filter as claimed in claim 9, wherein the end is correspondingly connected to the pin via welding, clipping or wrapping.

12. The filter as claimed in claim 9, wherein the pin comprises a recess.

13. The filter as claimed in claim 12, wherein the recess has a semicircular, square, rectangular, cambered or other shape.

14. The filter as claimed in claim 12, wherein the end is wound onto the recess and fixed by soldering.

15. The filter as claimed in claim 9, further comprising an adhesive covering the coil and filled between the coil and the board.

16. The filter as claimed in claim 9, further comprising a housing covering the coil leading structure.

17. The filter as claimed in claim 9, wherein the board comprises a printed circuit board.

18. The filter as claimed in claim 9, wherein the filter is applied to an electric device of local area network or ethernet.
